(19) United States
(12) Patent Application Publication
(10) Pub. No.: US 2022/0085188 A1
(43) Pub. Date: Mar. 17, 2022

(54) STACKED SEMICONDUCTOR CHIP STRUCTURE AND ITS PROCESS

(71) Applicants: Bo TU, GuangDong (CN); Hsiang-Yi CHENG, GuangDong (CN)

(72) Inventors: Bo TU, GuangDong (CN); Hsiang-Yi CHENG, GuangDong (CN)

(21) Appl. No.: 17/103,876

(22) Filed: Nov. 24, 2020

(30) Foreign Application Priority Data
Sep. 17, 2020 (CN) 202010978208.6

(51) Int. Cl. H01L 29/66; H01L 29/772; H01L 49/02

(52) U.S. Cl. CPC H01L 29/66409; H01L 29/772; H01L 21/0262; H01L 28/20; H01L 28/40

(57) ABSTRACT

The present invention discloses a stacked semiconductor chip structure and its process wherein the stacked semiconductor chip structure comprises a substrate as well as P-type semiconductor layers and N-type semiconductor layers which are stacked one by one on the substrate, wherein the P-type semiconductor layers and the N-type semiconductor layers are arranged alternately, there are at least two P-type semiconductor layers and at least two N-type semiconductor layers. The present invention uses the chemical vapor deposition method to stack and form the P-type semiconductor layers and the N-type semiconductor layers, uses the physical etching and the plasma cleaning to form the conducting layers and thus avoids using the photo masks, the photo resist and the mask aligners for the manufacture of semiconductor chips, reduces the complexity of semiconductor chip processes and increases the yield of semiconductor chip products.

### BACKGROUND OF THE INVENTION

The present invention relates to the field of semiconductor chip technology, in particular relates to a stacked semiconductor chip structure and its process.

Since the semiconductor chips appeared, all the manufacturing processes of diode, triode, NMOS, CMOS and LED products have required photo masks, photo resist, mask aligners, wet or plasma etching. As the minimum physical sizes of semiconductor chips constantly decrease, some powerful countries in Europe and America as well as Japan and South Korea have controlled the key technologies, materials, machines and patented technologies of the semiconductor chip industry, exploited, plundered and even forced out the electronic industry and basic industries of China. In order to develop and grow China, it is urgently necessary to change the situation in which semiconductor process patents are under the control of powerful countries and seek new semiconductor manufacturing processes which can completely get rid of photo masks, photo resist and mask aligners. The mask aligner is also called the stepping alignment exposing machine and is a technology similar to photo printing. The photo mask possesses the negative film function similar to photos; the photo resist is divided into positive photo resist or negative photo resist, similar to positive or negative film of a photographic plate. FIG. 1 shows a semiconductor manufacturing process using the photo mask, the photo resist and the mask aligner. Using mask aligners for the manufacture of semiconductor chips has the following disadvantages:

1) Some powerful countries in Europe and America as well as Japan have controlled the relevant machines, materials and patents, causing the crisis of sanction against the semiconductor industry of China;

2) The prior art is excessively complicated and strong acids can cause environmental pollution;

3) The minimum sizes of the prior art decrease to the nanometer level, but the mask aligners still use the spin-coating process and the thickness still remains about 5 μm. Therefore, the etching distance of 5 nanometers is formed between the photo resist with the height of 5 μm, the height ratio comes up to the terrible 1000 times, it is also usual that the height of relatively bigger minimum-sized photo resist is 200 times bigger than the etching distance, and as a result, it is not easy to control the process yields of photo resist and etching.

### BRIEF SUMMARY OF THE INVENTION

A technical purpose of the present invention is to provide a stacked semiconductor chip structure and its process and thus overcome the defect of the semiconductor chip processes based on existing technologies in which it is inevitable to use photo masks, photo resist and mask aligners.

To solve the technical defect described above, the present invention adopts the technical solution that:

A stacked semiconductor chip structure comprises a substrate as well as P-type semiconductor layers and N-type semiconductor layers which are stacked one by one on the substrate, wherein the P-type semiconductor layers and the N-type semiconductor layers are arranged alternately, there are at least two P-type semiconductor layers and at least two N-type semiconductor layers.

As an embodiment in accordance with the present invention that: the substrate is adjacent to one P-type semiconductor layer.

As an embodiment in accordance with the present invention that: the substrate is adjacent to one N-type semiconductor layer.

As an embodiment in accordance with the present invention that: there are a P-Well arranged in a P-type semiconductor layer.

As an embodiment in accordance with the present invention that: there is a conducting layer and an insulating layer arranged at least in a partial P-type semiconductor layer.

As an embodiment in accordance with the present invention that: the conducting layer and the insulating layer occupy a partial region of a P-type semiconductor layer.

As an embodiment in accordance with the present invention that: there are P-type heavy mingling regions P+ arranged in a P-Well.

As an embodiment in accordance with the present invention that: the conducting layer, the insulating layer, the P-Well and the P-type heavy mingling regions constitute the devices such as field effect transistors, capacitors or resistors in a structural manner and/or in a connection manner.

As an embodiment in accordance with the present invention that: there are N-Wells arranged in the N-type semiconductor layers.

As an embodiment in accordance with the present invention that: there are conducting layers and insulating layers arranged at least in some N-type semiconductor layers.

As an embodiment in accordance with the present invention that: the conducting layers and the insulating layers occupy partial regions of the N-type semiconductor layers.

As an embodiment in accordance with the present invention that: there are N-type heavy mingling regions N+ arranged in the N-Wells.

As an embodiment in accordance with the present invention that: the conducting layers, the insulating layers, the N-Wells and the N-type heavy mingling regions constitute the devices such as field effect transistors, capacitors or resistors in a structural manner and/or in a connection manner.

As an embodiment in accordance with the present invention that: the thickness of the substrate is set to fall in between 500 μm and 10,000 μm and the thickness of a P-type or N-type semiconductor layer is set to fall in between 0.1 μm and 10 μm.

A stacked semiconductor chip process, comprising the steps that:

A1. Arrange the substrate and then use the chemical vapor deposition method to arrange the P-type semiconductor layers on the substrate;

A2. Meanwhile, use the sputtering method to arrange the conducting layers in the P-type semiconductor layers, use the chemical vapor deposition method to arrange the insulating layers in the P-type semiconductor layers, use the chemical vapor deposition method to arrange the P-Wells in the P-type semiconductor layer and use the ionic implantation method to arrange the P-type heavy mingling regions in the P-Wells;

A3. Use the chemical vapor deposition method to arrange the N-type semiconductor layers on the P-type semiconductor layers;

A4. Meanwhile, use the sputtering method to arrange the conducting layers in the N-type semiconductor layers, use the chemical vapor deposition method to arrange the insulating layers in the N-type semiconductor layers, use the chemical vapor deposition method to arrange the N-Wells in the N-type semiconductor layers and use the ionic implantation method to arrange the N-type heavy mingling regions in the N-Wells;

A5. Use the chemical vapor deposition method to arrange the P-type semiconductor layers on the N-type semiconductor layers, repeat the Step A2;

A6. Repeat the Steps A3 and A4;

A7. Repeat the Step A5.

As an embodiment in accordance with the present invention that: The Step A2 includes the chemical or physical etching of the conducting layers.

As an embodiment in accordance with the present invention that: the physical etching includes the laser etching, the electron beam etching and the ion beam etching.

As an embodiment in accordance with the present invention that: the etching surfaces are treated with plasma cleaning or ultrasonic cleaning after the physical etching.

A stacked semiconductor chip process, comprising the steps that:

B1. Arrange the substrate and then use the chemical vapor deposition method to arrange the N-type semiconductor layers on the substrate;

B2. Meanwhile, use the sputtering method to arrange the conducting layers in the N-type semiconductor layers, use the chemical vapor deposition method to arrange the insulating layers in the N-type semiconductor layers, use the chemical vapor deposition method to arrange the N-Wells in the N-type semiconductor layer and use the ionic implantation method to arrange the N-type heavy mingling regions in the N-Wells;

B3. Use the chemical vapor deposition method to arrange the P-type semiconductor layer on the N-type semiconductor layer;

B4. Meanwhile, use the sputtering method to arrange the conducting layers in the P-type semiconductor layers, use the chemical vapor deposition method to arrange the insulating layers in the P-type semiconductor layers, use the chemical vapor deposition method to arrange the P-Wells in the P-type semiconductor layer and use the ionic implantation method to arrange the P-type heavy mingling regions in the P-Wells;

B5. Use the chemical vapor deposition method to arrange the N-type semiconductor layers on the P-type semiconductor layers, repeat the Step B2;

B6. Repeat the Steps B3 and B4;

B7. Repeat the Step B5.

As an embodiment in accordance with the present invention that: The Step B2 includes the chemical or physical etching of the conducting layers.

As an embodiment in accordance with the present invention that: The physical etching includes the laser etching, the electron beam etching and the ion beam etching.

As an embodiment in accordance with the present invention that: The etching surfaces are treated with plasma cleaning or ultrasonic cleaning after the physical etching.

The beneficial effects of the present invention that: The present invention uses the chemical vapor deposition method to stack and form the P-type semiconductor layers and the N-type semiconductor layers, uses the physical etching and the plasma cleaning to form the conducting layers and thus avoids using the photo masks, the photo resist and the mask aligners for the manufacture of semiconductor chips, reduces the complexity of semiconductor chip processes and increases the yield of semiconductor chip products.

### BRIEF DESCRIPTION OF THE DRAWINGS

The present invention is now described concretely with reference to the accompanying drawings and in combination with examples; the advantages and embodiments of the present invention will become more obvious wherein the content shown in the accompanying drawings are merely used to illustrate the present invention, not constituting any sense of limitations on the present invention, in the accompanying drawings:

FIG. 1 is a semiconductor chip process flowchart based on the prior art;

FIG. 2 is a schematic diagram of the stacked semiconductor chip structure based on the present invention;

FIG. 3 is a schematic diagram of a field effect transistor formed in the stacked semiconductor chip structure based on the present invention;

FIG. 4 is the stacked semiconductor chip process in the present invention.

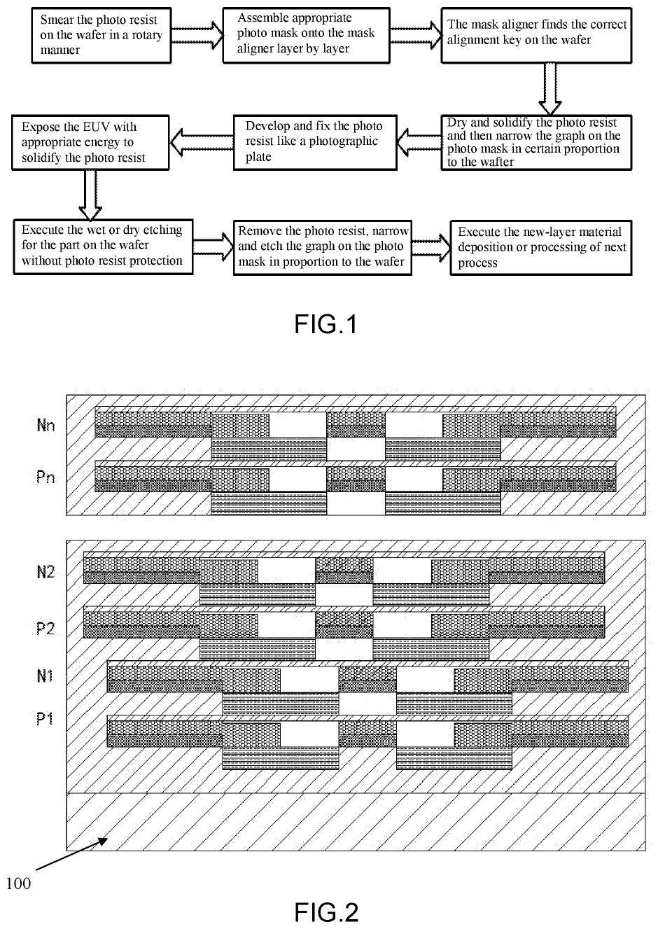

### DETAILED DESCRIPTION OF THE INVENTION

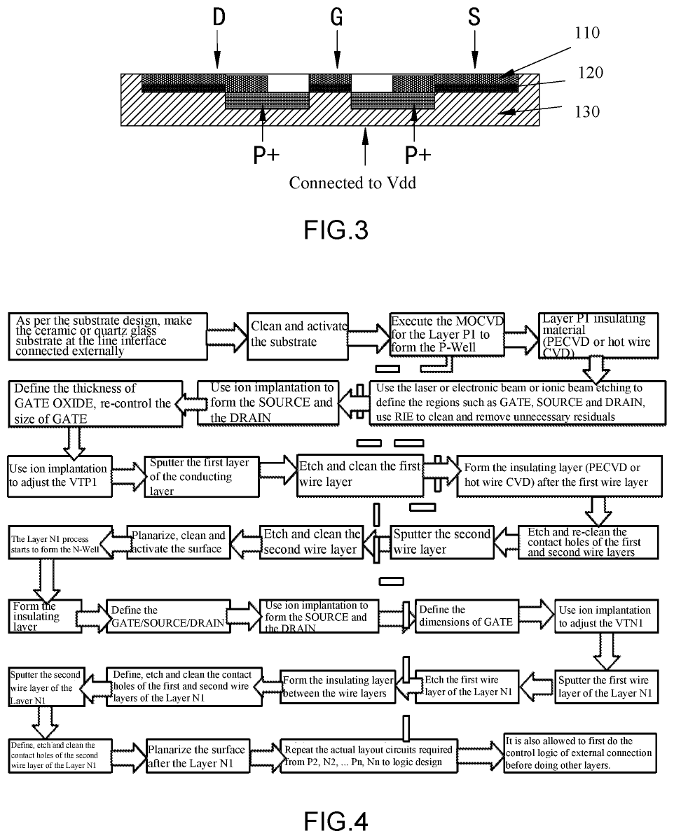

As shown in FIG. 2 and FIG. 3, a stacked semiconductor chip structure in accordance with the present invention comprises a substrate 100 as well as P-type semiconductor layers and N-type semiconductor layers which are stacked one by one on the substrate, wherein the P-type semiconductor layers and the N-type semiconductor layers are arranged alternately, there are at least two P-type semiconductor layers and at least two N-type semiconductor layers. As an embodiment in accordance with the present invention that: the substrate is adjacent to one P-type semiconductor layer. The substrate is adjacent to one N-type semiconductor layer. There is a P-Well 130 arranged in the P-type semiconductor layer. There is a conducting layer 110 and an insulating layer 120 arranged at least in a partial P-type semiconductor layer. The conducting layer 110 and the insulating layer 120 occupy a partial region of one N-type semiconductor layer. There are P-type heavy mingling regions P+arranged in the P-Well. The conducting layer 110, the insulating layer 120, the P-Well 130 and the P-type heavy mingling regions constitute the devices such as field effect transistors, capacitors or resistors in a structural manner and/or in a connection manner, and the thickness of the substrate is set to fall in between 500 μm and 10,000 μm and the thickness of a P-type or N-type semiconductor layer is set to fall in between 0.1 μm and 10 μm.

As another embodiment in accordance with the present invention that: there is a N-Well arranged in a N-type semiconductor layer. There is a conducting layer and an insulating layer arranged at least in a partial N-type semiconductor layer. The conducting layer and the insulating layer occupy a partial region of one N-type semiconductor layer. There are N-type heavy mingling regions N+ arranged in the P-Well. The conducting layer, the insulating layer, the N-Well and the N-type heavy mingling regions constitute the devices such as field effect transistors, capacitors or resistors in a structural manner and/or in a connection manner, and the thickness of the substrate is set to fall in between 500 μm and 10,000 μm and the thickness of a P-type or N-type semiconductor layer is set to fall in between 0.1 μm and 10 μm.

As shown in FIG. 4, the present invention discloses a stacked semiconductor chip process, comprising the steps that:

A1. Arrange the substrate 100 and then use the chemical vapor deposition method to arrange the P-type semiconductor layer on the substrate 100;

A2. Meanwhile, use the sputtering method to arrange the conducting layer 110 in the P-type semiconductor layer, use the chemical vapor deposition method to arrange the insulating layer 120 in the P-type semiconductor layer, use the chemical vapor deposition method to arrange the P-Well 130 in the P-type semiconductor layer and use the ionic implantation method to arrange the P-type heavy mingling region in the P-Wells 130;

A3. Use the chemical vapor deposition method to arrange the N-type semiconductor layer on the P-type semiconductor layer;

A4. Meanwhile, use the sputtering method to arrange the conducting layer in the N-type semiconductor layer, use the chemical vapor deposition method to arrange the insulating layer in the N-type semiconductor layer, use the chemical vapor deposition method to arrange the N-Well in the N-type semiconductor layer and use the ionic implantation method to arrange the N-type heavy mingling region in the N-Well;

A5. Use the chemical vapor deposition method to arrange the P-type semiconductor layer on the N-type semiconductor layers, repeat the Step A2;

A6. Repeat the Steps A3 and A4;

A7. Repeat the Step A5.

The Step A2 includes the chemical or physical etching of the conducting layer. The physical etching includes the laser etching, the electron beam etching and the ion beam etching. The etching surface is treated with plasma cleaning or ultrasonic cleaning after the physical etching.

As shown in FIG. 4, another embodiment of the stacked semiconductor chip process in accordance with the present invention comprises the steps that:

B1. Arrange the substrate and then use the chemical vapor deposition method to arrange the N-type semiconductor layer on the substrate;

B2. Meanwhile, use the sputtering method to arrange the conducting layer in the N-type semiconductor layer, use the chemical vapor deposition method to arrange the insulating layer in the N-type semiconductor layer, use the chemical vapor deposition method to arrange the N-Well in the N-type semiconductor layer and use the ionic implantation method to arrange the N-type heavy mingling region in the N-Well;

B3. Use the chemical vapor deposition method to arrange the P-type semiconductor layers on the N-type semiconductor layers;

B4. Meanwhile, use the sputtering method to arrange the conducting layer in the P-type semiconductor layer, use the chemical vapor deposition method to arrange the insulating layer in the P-type semiconductor layer, use the chemical vapor deposition method to arrange the P-Well in the P-type semiconductor layer and use the ionic implantation method to arrange the P-type heavy mingling region in the P-Well;

B5. Use the chemical vapor deposition method to arrange the N-type semiconductor layer on the P-type semiconductor layer, repeat the Step B2;

B6. Repeat the Steps B3 and B4;

B7. Repeat the Step B5.

The embodiment in accordance with the present invention, wherein the Step B2 includes the chemical or physical etching of the conducting layer. The physical etching includes the laser etching, the electron beam etching and the ion beam etching. The etching surface is treated with plasma cleaning or ultrasonic cleaning after the physical etching.

A purpose of the present invention is to solve the problems of the semiconductor manufacturing industry that it is a must to use photo masks, photo resists, mask aligners and wet etching and thus lower the costs, shorten the development cycle, reduce the environmental pollution and enable China to manufacture the semiconductors independently. To achieve the purpose described above, the present invention arranges any material which can carry semiconductor elements on the substrate; after improving the surface activity of substrate (ion bombardment or laser modification can be used to improve the surface activity of substrate), the present invention uses chemical vapor deposition to form the semiconductor well layer wherein the wells can be P-Wells or N-Wells and then form Sources, Drains and Gates wherein the 2D and 3D structures are formed directly via laser etching machines or electronic beams. The present invention uses the physical etching for the semiconductor process, directly forms the 3D structures via laser or electronic beams and uses the planarization process to ensure the accuracy of every subsequent layer. Most of cleaning steps in the present invention are the plasma cleaning, the ultrasonic cleaning and plasma bombardment, belonging to the zero or low-pollution processes. If it is integrated with sewage treatment and vacuum pump gas reclamation treatment, the present invention can conform to the corresponding environmental protection standard and cause no pollution. The plasma cleaning is also called dry etching; it can maintain certain vacuum degree in the vacuum cavity, inject appropriate plasma gas such as argon or inject different gases as per different etching materials to form plasma gas or reactant gas and thus reach an appropriate etching ratio for cleaning. In addition to forming active elements, this process also can form passive elements; it places one insulating layer between the wires of two layers to form a capacitor. The wires and the wells can form a resistor and the impedance elements also can form the design rules as per mass data. Its manufacturing process can come into being due to layout and it is not necessary to use the layers specially and independently. Capacitor forming method: It places a dielectric substance between two adjacent conducting layers with identical area to form a capacitor. Resistor forming method: It is allowed to use P-Well or N-Wells to form resistors; it is also allowed to use the wires of conducting layers with different widths to form different resistors, it is also allowed to use contact holes with different sizes to connect the P-Wells or N-Wells in series to form resistors.

As shown in FIG. 2, take the P-type layers as an example, for the adjustment of P+ and VTP (the initial voltage of P-type semiconductors), it is necessary to use the ion implantation technology (which separates the negative and positive ions of gas, chooses and accelerates appropriate ions in the electromagnetic fields to an appropriate function, and then change the ion mingling ratio in the semiconductors to form the P-Wells or N-Wells or P+ or N+ regions or adjust the initial voltage). After the P-Well layers are formed, smear the materials with approximate coefficients of thermal expansion in a rotary manner on the surfaces of elements for solidification, and then use the PECVD (PLASMA ENHANCE CHEMICAL VAPOR DEPOSITION) to activate the insulating layers, and then use the MOCVD (METAL ORGANIC CHEMICAL VAPOR DEPOSITION) to form the N-Wells and repeat the generation of N+ and elements. When the wire layers are going to form, connect the elements and interconnections of the P-Well and N-Well layers. Materials with the coefficients of thermal expansion: Metallic materials, polymers, non-metallic materials, glass and so on have different coefficients of thermal expansion; the process based on the present invention mainly uses the materials with approximate coefficients of thermal expansion to prevent expansion and contraction from causing the loss of reliability. Alternately turn the P-Wells and the N-Wells as per logic design to the circuit design and then arrange and connect all the elements and interconnections. After connecting all the elements and interconnections in sequence, thicken the conducting layers and leave bond pads and then successively switch to the subsequent assembly process as per the design rules. Planarization process: Use the frictioning method to smear the sodium silicate on the surfaces of chips, dry and planarize the surfaces, and then execute the plasma enhance chemical vapor deposition of SiO2 or the chemical vapor deposition of hot wires and use the compacting technology to enable the density and the planarization degree to meet the corresponding criteria. VTN is the initial voltage of N-type semiconductors.

Compared to the conventional semiconductor manufacturing process, the present invention has the following characteristics that:

1. It substitutes a laser etching machine or an ion beam etching machine for a mask aligner.

1.1. China has obvious advantages in the machines such as laser etching machines, or ion beam etching machines or electronic beam etching machines. The mask aligners are completely monopolized by foreign countries.

1.2. Can realize intelligent alignment and thus improve the yield.

2. It needs no photo resist.

2.1. The spin-coating thickness of photo resist is at the micron level while the semiconductor processes have been required to be at the nanometer level, equivalently opening a one-meter road in a 1 km-high wall, in a word, the requirement is excessively strict.

2.2. Meanwhile, it can avoid many high-pollution and yield-affecting behaviors such as photo resist developing, fixing, drying and removal.

2.3. For the wet etching, it can be avoided because it is a process characterized by high toxicity and high pollution.

2.4. For the dry etching, its height and width are relatively approximate, so it is easier to carry out the dry etching and the yield also can be increased significantly.

3. It can lower the construction costs of semiconductor plants by 50%-80% from hundreds of billions of US dollars to hundreds of billions Renminbi.

4. All the relevant machines, materials and patents can be made domestically. The relevant machines, materials and patents even can be integrated into one industrial park. This can significantly increase the comprehensive competitiveness of China in the field of semiconductors.

Without departing from the essence and spirit of the present invention, the skilled people in the art can use various variation schemes to realize the present invention; the above embodiments are merely the preferred and feasible embodiments of the present invention, not limiting the scope of Claims of the present invention; all the equivalent structural changes made as per the Specifications and Drawings of the present invention shall be covered in the scope claimed by the present invention.

What is claimed is:

1. A stacked semiconductor chip structure comprises a substrate as well as P-type semiconductor layers and N-type semiconductor layers which are stacked one by one on the substrate, wherein the P-type semiconductor layers and the N-type semiconductor layers are arranged alternately, there are at least two P-type semiconductor layers and at least two N-type semiconductor layers.

2. The stacked semiconductor chip structure in accordance with claim 1, wherein the substrate is adjacent to one P-type semiconductor layer.

3. The stacked semiconductor chip structure in accordance with claim 1, wherein the substrate is adjacent to one N-type semiconductor layer.

4. The stacked semiconductor chip structure in accordance with claim 1, wherein there are P-Wells arranged in the P-type semiconductor layers.

5. The stacked semiconductor chip structure in accordance with claim 4, wherein there are conducting layers and insulating layers arranged at least in some P-type semiconductor layers.

6. The stacked semiconductor chip structure in accordance with claim 5, wherein the conducting layers and the insulating layers occupy partial regions of the P-type semiconductor layers.

7. The stacked semiconductor chip structure in accordance with claim 6, wherein there are P-type heavy mingling regions P+arranged in the P-Wells.

8. The stacked semiconductor chip structure in accordance with claim 7, wherein the conducting layers, the insulating layers, the P-Wells and the P-type heavy mingling regions constitute the devices such as field effect transistors, capacitors or resistors in a structural manner and/or in a connection manner.

9. The stacked semiconductor chip structure in accordance with claim 1, wherein there are N-Wells arranged in the N-type semiconductor layers.

10. The stacked semiconductor chip structure in accordance with claim 9, wherein there are conducting layers and insulating layers arranged at least in some N-type semiconductor layers.

11. The stacked semiconductor chip structure in accordance with claim 10, wherein the conducting layers and the insulating layers occupy partial regions of the N-type semiconductor layers.

12. The stacked semiconductor chip structure in accordance with claim 11, wherein there are N-type heavy mingling regions N+arranged in the N-Wells.

13. The stacked semiconductor chip structure in accordance with claim 12, wherein the conducting layers, the insulating layers, the N-Wells and the N-type heavy mingling regions constitute the devices such as field effect transistors, capacitors or resistors in a structural manner and/or in a connection manner.

14. The stacked semiconductor chip structure in accordance with claim 1, wherein: The thickness of the substrate is set to fall in between 500 μm and 10,000 μm and the thickness of a P-type or N-type semiconductor layer is set to fall in between 0.1 μm and 10 μm.

15. A stacked semiconductor chip process, comprising the steps that:
A1. Arrange the substrate and then use the chemical vapor deposition method to arrange the P-type semiconductor layers on the substrate;
A2. Meanwhile, use the sputtering method to arrange the conducting layers in the P-type semiconductor layers, use the chemical vapor deposition method to arrange the insulating layers in the P-type semiconductor layers, use the chemical vapor deposition method to arrange the P-Wells in the P-type semiconductor layer and use the ionic implantation method to arrange the P-type heavy mingling regions in the P-Wells;
A3. Use the chemical vapor deposition method to arrange the N-type semiconductor layers on the P-type semiconductor layers;
A4. Meanwhile, use the sputtering method to arrange the conducting layers in the N-type semiconductor layers, use the chemical vapor deposition method to arrange the insulating layers in the N-type semiconductor layers, use the chemical vapor deposition method to arrange the N-Wells in the N-type semiconductor layers and use the ionic implantation method to arrange the N-type heavy mingling regions in the N-Wells;
A5. Use the chemical vapor deposition method to arrange the P-type semiconductor layers on the N-type semiconductor layers, repeat the Step A2;
A6. Repeat the Steps A3 and A4;
A7. Repeat the Step A5.

16. The stacked semiconductor chip process in accordance with claim 15, wherein the Step A2 includes the chemical or physical etching of the conducting layers.

17. The stacked semiconductor chip process in accordance with claim 16, wherein the physical etching includes the laser etching, the electron beam etching and the ion beam etching.

18. The stacked semiconductor chip process in accordance with claim 17, wherein the etching surfaces are treated with plasma cleaning or ultrasonic cleaning after the physical etching.

19. A stacked semiconductor chip process, wherein it comprises the steps that:
B1. Arrange the substrate and then use the chemical vapor deposition method to arrange the N-type semiconductor layers on the substrate;
B2. Meanwhile, use the sputtering method to arrange the conducting layers in the N-type semiconductor layers, use the chemical vapor deposition method to arrange the insulating layers in the N-type semiconductor layers, use the chemical vapor deposition method to arrange the N-Wells in the N-type semiconductor layers and use the ionic implantation method to arrange the N-type heavy mingling regions in the N-Wells;
B3. Use the chemical vapor deposition method to arrange the P-type semiconductor layers on the N-type semiconductor layers;
B4. Meanwhile, use the sputtering method to arrange the conducting layers in the P-type semiconductor layers, use the chemical vapor deposition method to arrange the insulating layers in the P-type semiconductor layers, use the chemical vapor deposition method to arrange the P-Wells in the P-type semiconductor layer and use the ionic implantation method to arrange the P-type heavy mingling regions in the P-Wells;
B5. Use the chemical vapor deposition method to arrange the N-type semiconductor layers on the P-type semiconductor layers, repeat the Step B2;
B6. Repeat the Steps B3 and B4;
B7. Repeat the Step B5.

20. The stacked semiconductor chip process in accordance with claim 19, wherein the Step B2 includes the chemical or physical etching of the conducting layers.

21. The stacked semiconductor chip process in accordance with claim 20, wherein the physical etching includes the laser etching, the electron beam etching and the ion beam etching.

22. The stacked semiconductor chip process in accordance with claim 21, wherein the etching surfaces are treated with plasma cleaning or ultrasonic cleaning after the physical etching.
